(19) United States
(12) Patent Application Publication
(10) Pub. No.: US 2013/0333835 A1
(43) Pub. Date: Dec. 19, 2013

(54) PROCESS FOR MANUFACTURING GAS PERMEATION BARRIER MATERIAL AND STRUCTURE

(71) Applicants: Peter Francis Carcia, Wilmington, DE (US); Robert Scott Mclean, Hockessin, DE (US)

(72) Inventors: Peter Francis Carcia, Wilmington, DE (US); Robert Scott Mclean, Hockessin, DE (US)

(73) Assignee: E I DU PONT DE NEMOURS AND COMPANY, Wilmington, DE (US)

(21) Appl. No.: 13/523,439

(22) Filed: Jun. 14, 2012

(51) Int. Cl. C23C 16/06; C23C 16/38; B32B 37/00; C23C 16/40

(52) U.S. Cl. 156/280; 427/255.28; 427/255.29; 427/255.394; 427/255.36; 427/255.31; 427/255.34; 427/255.35; 427/255.37; 156/60; 427/96.8

(57) ABSTRACT

Hybrid inorganic-organic, polymeric alloys are prepared by combining atomic layer deposition and molecular layer deposition techniques provide barrier protection against intrusion of atmospheric gases such as oxygen and water vapor. The alloy may be formed either directly on objects to be protected, or on a carrier substrate to form a barrier structure that subsequently may be employed to protect an object. The alloy thus formed is beneficially employed in constructing electronic devices such as photovoltaic cell arrays, organic light-emitting devices, and other optoelectronic devices.

### CROSS-REFERENCE TO RELATED APPLICATIONS

This application is related to a co-pending application entitled “Gas Permeation Barrier Material” and bearing attorney docket number CL5414 US-NP; and a co-pending application entitled “Electronic Device With Gas Permeation Barrier Protective Coating” and bearing attorney docket number CL5767 US-NP, said applications being filed of even date herewith by the same inventors. Each of these applications is incorporated herein in its entirety for all purposes by reference thereto.

### FIELD OF THE INVENTION

This invention relates to a barrier material, and more particularly, to a process for manufacturing hybrid inorganic-organic polymeric gas permeation barrier materials, structures and devices made therewith.

### BACKGROUND

A wide variety of industrial and commercial products and devices require some level of protection from ambient oxygen and/or water vapor to prevent degradation or failure. Some items can readily be sealed within a rigid, possibly metallic, hermetic structure, but for other items, a flexible structure is desired or required. For example, certain types of low-cost polymer films afford adequate short-term protection for foodstuffs and other consumer goods, notwithstanding the relatively facile permeation of oxygen and water vapor through them. It is generally believed that typical polymers have an inherently high free volume fraction that provides diffusion pathways that give rise to the observed level of permeability. A thin metallization can give a substantial improvement, but makes the polymer film opaque. Aluminum-coated polyester is one such material in common use.

However, optical transparency is desirable or essential for some applications. For example, polymers with an optically transparent, inorganic barrier layer are used in some food, beverage, and pharmaceutical packaging. Barrier materials such as SiOₓ and AlO_{y} can be applied either by physical vapor deposition (PVD) or chemical vapor deposition (CVD), producing materials known in the industry as “glass-coated” barrier films. They provide an improvement for atmospheric gas permeation of about 10×, reducing transmission rates to about 1.0 cc O₂/m²/day and 1.0 ml H₂O/m²/day through polyester film (M. Izu, B. Dotter, and S. R. Ovshinsky, J. Photopolymer Science and Technology., vol. 8, 1995, pp. 195-204). While this modest improvement is a reasonable compromise between better properties and cost for many high-volume packaging applications, the protection afforded still falls far short of the far more challenging requirements for many electronic devices. Packaging of consumer goods is typically required only to maintain the items in suitable condition through manufacturing and distribution and for a defined, relatively short shelf life thereafter. On the other hand, electronic articles must operate satisfactorily over the entire useful life of the product, which is often an order of magnitude longer or more. In most instances, the electronic devices use materials that react with water and/or oxygen; exposure to these contaminants can unacceptably degrade device performance. Thus, an improvement in resistance to gas permeation by a factor of 10⁴-10⁶ may be required. While known inorganic coatings provide some reduction of the permeability, the levels typically attained are still inadequate. Both microstructural features and larger-scale defects are believed to contribute.

Ideally, a thin-film coating, e.g., with an inorganic material, that is both continuous and free from such defects should be adequate. However, the practical reality is that even elimination of obvious macroscopic defects such as pinholes that arise either from the coating process or from substrate imperfections, is still not enough to provide protection sufficient to maintain the desired device performance in practical devices.

For example, it is known that even microscopic cracks in a coating compromise its protective ability, providing a facile pathway for ambient gases to intrude. Such cracks can arise either during coating formation or thereafter.

CVD and PVD and other deposition methods commonly used to deposit inorganic materials generally entail initiation and film growth at discrete nucleation sites. The resulting materials ordinarily have microstructural features that create pathways that allow gas permeation. The PVD method is known to be particularly prone to creation of columnar microstructures having grain boundaries and other comparable defects, along which gas permeation can be especially facile.

Display devices based on organic light emitting polymers (OLEDs) exemplify the need for exacting protection, e.g., a barrier improvement of ˜10⁵-10⁶× over what is attainable with present flexible barrier materials having a PVD or CVD coating. Both the light-emitting polymer and the cathode (typically made with Ca or Ba metal) are water-sensitive. Without adequate protection, device performance may degrade rapidly.

Photovoltaic (PV) cells provide another example. To capture sunlight, these devices are necessarily mounted in outdoor locations exposed to harsh conditions of temperature and moisture, including precipitating snow and rain. To be economically viable, a long usable lifetime, e.g., at least 25 years, is presumed for PV installations.

PV cells based on thin-film technologies such as amorphous silicon (a-Si), cadmium telluride (CdTe), copper indium (gallium) di-selenide/sulfide (CIS/CIGS), and dye-sensitized, organic and nano-materials are of great current interest, because of their potential to provide high efficiency conversion. Moisture sensitivity is an issue for all these technologies, but is particularly acute for CIGS-based PV cells. To achieve a 25-year lifetime, a CIGS-based cell needs a barrier with a water vapor transmission rate <5×10⁻⁴ g-H₂O/m² day. Despite this stringent requirement, PV cells based on CIGS and related materials are attractive because of the high efficiency (˜20%) they have exhibited in small laboratory-size experiments under controlled conditions.

Forms of various electronic devices such as thin-film PV cells and OLED devices constructed on flexible substrates are highly desired. Such a configuration would facilitate shipping and installation, e.g., permitting PV integration into a roof-top membrane supplied in roll form or installation of an OLED display on a non-planar surface. In addition, flexible substrates potentially would also reduce the overall device thickness.

However, substrate flexure inherently imposes stress on any coating layer. If strain limits are exceeded, the coating may crack, likely compromising any barrier properties the coating provides, as the cracks create a facile diffusion pathway for contaminants to intrude, potentially causing device failure.

A number of approaches have been suggested to mitigate these vulnerabilities, including multilayer structures consisting of identifiable, alternating layers of different materials, which may be of nanometer-range thickness. The multilayer structures proposed include ones having alternating inorganic layers of different types and ones having alternating polymeric and inorganic layers. It has been postulated that such a structure decouples individual defects, so that no one defect persists through most or all of the coating thickness. Nevertheless, none of the coatings proposed heretofore has alleviated all the detriments.

Thus, there remains a need for flexible substrates, protective structures, and barrier materials, particularly ones that meet the needs for constructing and packaging electronic devices, including thin-film PV cells, OLEDs, and the like.

### SUMMARY OF THE INVENTION

One aspect of the present invention provides, as a composition of matter, an alloy comprising an inorganic substance and a metalcone that are polymerically linked. In various embodiments, the inorganic substance is an oxide or nitride, such as an oxide or nitride of an element of Groups IVB, VB, VIB, IIIA, or IVA of the Periodic Table, or a combination of such elements, and the metalcone is an alucone, zincone, titanicone, or zircone.

Another aspect provides a barrier substrate comprising:

(a) a carrier substrate having opposing first and second major surfaces; and
(b) a barrier coating disposed on the first major surface of the carrier substrate and comprising an alloy comprising an inorganic substance and a metalcone that are polymerically linked.

Still another embodiment provides an electronic device comprising a circuit element and a barrier coating disposed on the circuit element and comprising an alloy comprising an inorganic substance and a metalcone that are polymerically linked.

Further provided is a process for manufacturing an alloy, comprising the steps of:
(a) providing a substrate in a reaction zone;
(b) carrying out a first deposition sequence comprising at least one first deposition cycle comprising in sequence the steps of:
   (b1) admitting into the reaction zone a first reactant precursor vapor capable of forming an adsorbed layer on the substrate,
   (b2) purging the reaction zone to remove unadsorbed first reactant precursor vapor,
   (b3) admitting into the reaction zone a second reactant precursor vapor under thermal conditions that promote a reaction of the second reactant precursor vapor and adsorbed first reactant precursor vapor, and
   (b4) purging the reaction zone of volatile reactants and reaction products produced in step (b3);
(c) thereafter carrying out a second deposition sequence comprising at least one second deposition cycle comprising in sequence the steps of:
   (c1) admitting into the reaction zone a third reactant precursor vapor capable of forming an adsorbed layer on the substrate,
   (c2) purging the reaction zone to remove unadsorbed third reactant precursor vapor,
   (c3) admitting into the reaction zone a fourth reactant precursor vapor under thermal conditions that promote a reaction of the fourth reactant precursor vapor and adsorbed third reactant precursor vapor, and
   (c4) purging the reaction zone of volatile reactants and reaction products produced in step (c3); and
(d) thereafter repeating in alternation the first and second deposition sequences for a number of times sufficient to form the alloy on the substrate in a preselected thickness

Yet another aspect provides a process for manufacturing a barrier structure, comprising the steps of:
(a) providing a carrier substrate having opposing first and second major surfaces in a reaction zone; and
(b) carrying out a first deposition sequence comprising at least one first deposition cycle comprising in sequence the steps of:
   (b1) admitting into the reaction zone a first reactant precursor vapor capable of forming an adsorbed layer on at least the first major surface of the carrier substrate,
   (b2) purging the reaction zone to remove unadsorbed first reactant precursor vapor,
   (b3) admitting into the reaction zone a second reactant precursor vapor under thermal conditions that promote a reaction of the second reactant precursor vapor and adsorbed first reactant precursor vapor, and
   (b4) purging the reaction zone of volatile reactants and reaction products produced in step (b3);
(c) thereafter carrying out a second deposition sequence comprising at least one second deposition cycle comprising in sequence the steps of:
   (c1) admitting into the reaction zone a third reactant precursor vapor capable of forming an adsorbed layer on at least the first major surface of the carrier substrate,
   (c2) purging the reaction zone to remove unadsorbed third reactant precursor vapor,
   (c3) admitting into the reaction zone a fourth reactant precursor vapor under thermal conditions that promote a reaction of the fourth reactant precursor vapor and adsorbed third reactant precursor vapor, and,
   (c4) purging the reaction zone of volatile reactants and reaction products produced in step (c3); and
(d) thereafter repeating in alternation the first and second deposition sequences for a number of times sufficient to form the alloy on at least the first major surface of the carrier substrate in a preselected thickness.

Still a further aspect provides a process for constructing an electronic device comprising:
(a) providing a circuit element having opposing first and second sides; and
(b) applying onto the first side of the circuit element a barrier coating comprising an alloy comprising an inorganic substance and a metalcone that are polymerically linked.

In yet another aspect, there is provided a process for constructing an electronic device comprising:
(a) providing a circuit element having opposing first and second sides; and
(b) affixing onto the first side of the circuit element a first barrier structure comprising a carrier substrate having opposing first and second major surfaces and a barrier coating disposed on the first major surface of the carrier substrate and comprising an alloy comprising an inorganic substance and a metalcone that are polymerically linked.

### BRIEF DESCRIPTION OF THE FIGURES

The invention will be more fully understood and further advantages will become apparent when reference is made to the following detailed description of the preferred embodiments of the invention and the accompanying drawings, wherein like reference numeral denote similar elements throughout the several views and in which:

FIGS. 1A to 1D depict in schematic form a chemical reaction sequence illustrative of atomic layer deposition of an alumina inorganic oxide coating;

FIGS. 2A to 2D depict in schematic form a chemical reaction sequence illustrative of molecular layer deposition of an alucone hybrid inorganic-organic polymer;

FIGS. 3A to 3F depict in schematic form a chemical reaction sequence illustrative of the deposition of an alloy comprising an inorganic oxide and an alucone hybrid inorganic-organic polymer that are polymerically linked;

FIG. 4 depicts schematically an apparatus in which a material can be deposited on a surface or a device;

FIG. 5 is a graph relating the water vapor transmission rate through a barrier material to its composition;

FIG. 6 is a graph relating the water vapor transmission rate through another barrier material to its composition;

FIG. 7 is a graph relating average film cracking density and strain in a barrier material;

FIG. 8 is a graph relating critical tensile strain to the composition of various barrier materials;

FIG. 9 depicts a light-emitting polymer device with a barrier substrate and a barrier top coat;

FIG. 10 depicts a light-emitting polymer device with a barrier substrate and a barrier capping layer.

FIG. 11 depicts an organic transistor with a barrier substrate and a barrier capping layer.

FIG. 12 depicts an organic transistor with a barrier substrate and a barrier capping layer.

### DETAILED DESCRIPTION

In one aspect, the present disclosure provides a barrier material that is an alloy of materials that may be formed as a thin film by combining atomic layer deposition (ALD) and molecular layer deposition (MLD) techniques. It has been found that in some embodiments, a barrier material that intimately combines an inorganic substance polymerically linked with a hybrid organic-inorganic polymer provides a combination of low permeability for atmospheric gases such as oxygen and water vapor with improved mechanical properties.

In another aspect, the present disclosure provides a barrier structure comprising a carrier substrate and a barrier coating layer. The barrier coating comprises an alloy formed by a combination ALD/MLD process. Typically, the carrier substrate is relatively thin and in the form of a plate, sheet, or the like, having one of its dimensions much smaller than the other two, thereby defining first and second major surfaces that are in an opposing relationship. The barrier coating layer ordinarily is applied to one or both of the major surfaces.

The barrier structure is useful for preventing the passage of atmospheric gases and may be employed in constructing a variety of devices for which protection is sought. In general, the substrate may comprise metal, polymer, or glass. Thin metal and polymer substrates have the advantage of being flexible; glass and some polymers have the advantage of being transparent or translucent. Suitable carrier substrates include both glasses and the general class of polymeric materials, such as described by but not limited to those in Polymer Materials, (Wiley, New York, 1989) by Christopher Hall or Polymer Permeability, (Elsevier, London, 1985) by J. Comyn. Common examples include polyesters such as polyethylene terephthalate (PET) and polyethylene naphthalate (PEN), polyamides, polyacrylates, polyimides, polycarbonates, polyarylates, polyethersulfones, polycyclic olefins, fluoropolymers such as polytetrafluoroethylene (PTFE), polyvinyl fluoride (PVA), perfluoroalkoxy copolymer (PFA), or fluorinated ethylene propylene (FEP), and the like. Both flexible and rigid forms of these polymers may be used. Many flexible polymer materials are commercially available as film base by the roll, and may be suitable for encapsulating devices, such as thin-film photovoltaic devices, organic light-emitting diode devices, and the like. Thus, barrier structures formed by depositing barrier coatings on any of the foregoing substrates may be either rigid or flexible. In some embodiments, the barrier layers resist formation of cracks or like defects during flexure, so that the layers retain a high resistance to gas permeation. In addition to the alloy coating provided herein, the substrate may also include other functional coatings used to enhance other optical, electrical, or mechanical properties that are beneficial in an end-use application.

In a related aspect, an electronic or other device can be protected either by applying the barrier coating directly to it or by disposing the barrier coating on a rigid or flexible substrate material that is sealed to the device.

### Atomic Layer Deposition

Atomic layer deposition (ALD) is a method that permits growth of films on substrates or other objects of various types. A description of the ALD process can be found in “Atomic Layer Epitaxy,” by Tuomo Suntola, Thin Solid Films, vol. 216 (1992) pp. 84-89.

As the name implies, the ALD process forms a film by repeatedly depositing atoms of the requisite material in a layer-by-layer sequence. The ALD process is typically accomplished in a chamber using a two-stage reaction. The process steps are carried out repetitively to build up sublayers layers that together form a coating of the requisite thickness. First, a vapor of film precursor is introduced into the chamber. Without being bound by any theory, it is believed that a thin layer of the precursor, usually essentially a monolayer, is adsorbed on a substrate or device in the chamber. As used herein, the term “adsorbed layer” is understood to mean a layer whose atoms are chemically bound to the surface of a substrate. Thereafter, the vapor is purged from the chamber, e.g., by evacuating the chamber or by flowing an inert purging gas, to remove any excess or unadsorbed vapor. A reactant is then introduced into the chamber under thermal conditions that promote a chemical reaction between the reactant and the adsorbed precursor to form a sublayer of the desired barrier material. The volatile reaction products and excess precursors are then pumped from the chamber. Additional sublayers of material are formed by repeating the foregoing steps for a number of times sufficient to provide a layer having a preselected thickness. Although capable of producing films of a number of types, ALD is most commonly used to deposit inorganic oxides and nitrides, such as aluminum, silicon, zinc, or zirconium oxide and silicon or aluminum nitride. In some instances, the oxides and nitrides produced by ALD may deviate slightly from the stoichiometry of the corresponding bulk material, but still provide the necessary functionality.

Materials formed by ALD that are suitable for barriers include, without limitation, oxides and nitrides of elements of Groups IVB, VB, VIB, IIIA, and IVA of the Periodic Table and combinations thereof. Particular examples of these materials include Al₂O₃, SiO₂, TiO₂, ZrO₂, HfO₂, MoO₃, SnO₂, In₂O₃, Ta₂O₅, Nb₂O₅, SiNₓ, and AlNₓ. Of particular interest in this group are SiO₂, Al₂O₃, TiO₂, ZrO₂, and Si₃N₄. Another possible substance is ZnO. Most of these oxides beneficially exhibit optical transparency, making them attractive for electronic displays, photovoltaic cells, and other optoelectronic devices, wherein visible light must either exit or enter the device during normal operation. The nitrides of Si and Al are also transparent in the visible spectrum. The term “visible light” as used herein includes electromagnetic radiation having a wavelength that falls in the infrared and ultraviolet spectral regions, as well as wavelengths generally perceptible to the human eye, all being within the operational limits of typical optoelectronic devices.

The precursors useful in ALD processes include those tabulated in published references such as M. Leskela and M. Ritala, “ALD precursor chemistry: Evolution and future challenges,” in Journal de Physique IV, vol. 9, pp. 837-852 (1999) and references therein.

In a representative embodiment, the ALD process can be accomplished using a two-step deposition that is repetitively carried out at a surface to build up a layer of the desired ALD material. Conceptually, the deposition reaction can be represented using the following schematic steps:

(A) SOH*+MRₓ→SOMRₓ₋₁*+RH (1)

(B) SOMR*+H₂O→SOMOH*+RH (2)

wherein S indicates the existing surface at each step, R is an organic group, M is a metal atom, and the asterisk “*” indicates a surface species.

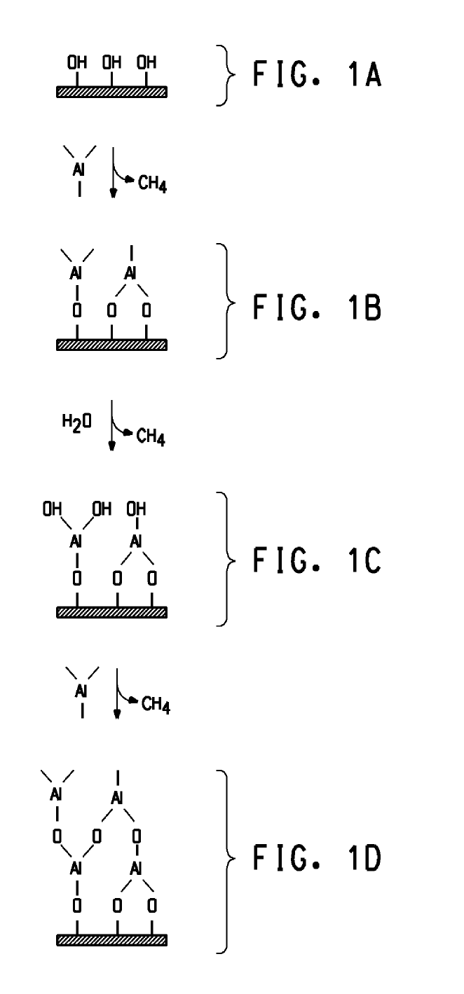

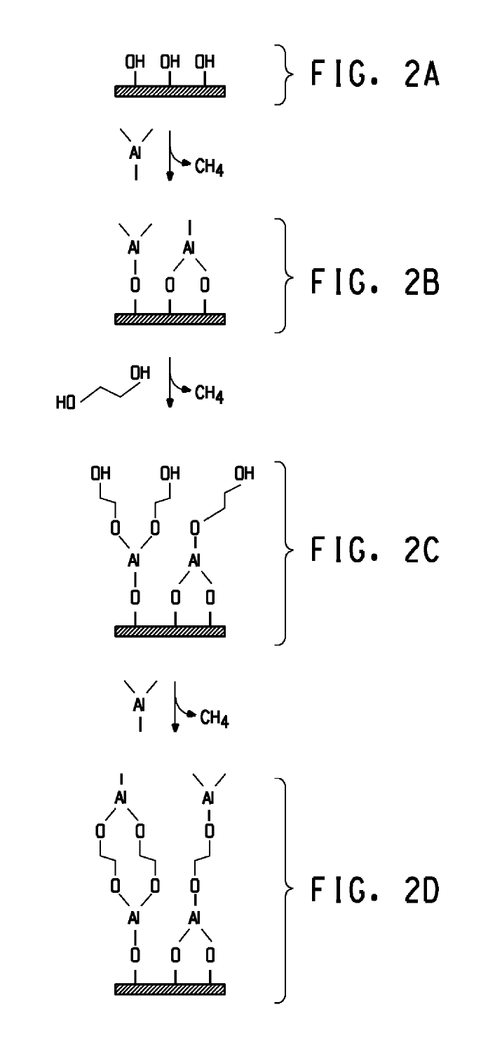

In one exemplary embodiment of this reaction scheme, aluminum oxide (alumina) may be formed by using trimethylaluminum (TMA) and water vapor in alternation as the film precursor and reactant, as illustrated schematically in FIGS. 1A to 1D. TMA reacts with the pendant native surface hydroxyls of FIG. 1A to form Al—O linkages. A free methane molecule is formed for each linkage produced (FIG. 1B). The next exposure to water (or, alternatively, another oxidant such as ozone) (FIG. 1C) displaces the methyl groups remaining from the TMA, leaving pendant hydroxyls. The reaction sequence then continues with another TMA exposure (FIG. 1D). Further continuation of the sequence results in an alumina film of selectable thickness. Of course, the ALD process may be carried out with other precursors and reactants.

Layers of alumina as thin as 25 nm or less produced by ALD have been shown to provide an effective permeation barrier that can inhibit transmission of oxygen and water below the limits of detectability of conventional instrumentation. For example, US Patent Publication US2008/0182101 to Carcia et al. provides a 25 nm-thick aluminum oxide film on PEN that has an oxygen transmission rate of below 0.005 cc-O₂/m²/day.

As noted above, previous CVD and PVD deposition methods typically result in films having microstructural growth features that permit facile gas permeation. In contrast, ALD can produce very thin films with extremely low gas permeability, making such films attractive as barrier layers for protecting sensitive electronic devices, including PV cells, organic light emitting devices (OLEDs), and other optoelectronic devices that are sensitive to the intrusion of moisture and/or oxygen. The ALD deposition occurs by a surface reaction that proceeds layer-by-layer, so it is inherently self-limiting and produces a highly conformal coating. The ALD layer can be formed either directly on a device itself or on a substrate, possibly flexible, that is thereafter affixed to a device or its mounting. This allows a wide range of devices, including those with complex topographies, to be fully coated and protected. In an embodiment, films produced by ALD are amorphous and exhibit a featureless microstructure.

Existing inorganic thin films, including those grown by ALD, can be vulnerable to cracking that may degrade their barrier properties. It is believed that the cracking is attributable to the relative brittleness of many of the inorganic materials as deposited. The stresses that give rise to cracking have a variety of causes. For example, cracks in the ALD film can form either during the deposition itself or upon flexure of the film/substrate laminate. Common polymeric substrates can have a coefficient of thermal expansion (CTE) more than 10 times that of typical inorganic oxides or nitrides. The mismatch thereby induces strains during cool-down after a deposition, which is commonly run at 100° C. or more. Coatings on flexible substrates are also vulnerable during flexure to a small radius of curvature, which puts the coating material under stresses that may exceed the yield limit. As noted above, cracks are believed to permit facile intrusion of oxygen and water vapor from the ambient atmosphere, which may compromise the performance of a device being protected by an ALD barrier.

### Molecular Layer Deposition

It is known in the art that by changing the reactants, a hybrid organic-inorganic polymer can be formed in a process complementary to the ALD process. Such a process is commonly termed “molecular layer deposition” (MLD). MLD processes, like their ALD counterparts, sequentially deposit reaction products layer by layer to build a desired thickness. At each step of the sequence, the reaction is self-limiting and so highly conformal films are produced.

Typically the MLD reaction combines an inorganic reactant, including reactants useful in common ALD processes, with an organic reactant. In one possible implementation, an MLD process entails the reaction of a multifunctional inorganic monomer with a homo- or hetero-multifunctional organic monomer to form a hybrid organic-inorganic, metal alkoxide polymer, herein termed a “metalcone.” One such MLD process that can be used to form such a polymer entails reacting an oxygen-containing species, such as an organic alcohol or diol precursor, with an organometallic precursor.

In an exemplary embodiment, a metalcone may be produced by reacting a diol with a metal alkyl in a two-step reaction that is repetitively carried out at a surface to build up a layer of the metalcone. The reaction steps can be written schematically as:

(A) SOH*+MRₓ→SOMRₓ₋₁*+RH (3)

(B) SOMR*+HOR′OH→SOMOR′OH*+RH (4)

wherein S again indicates the existing surface at each step, R and R′ are organic groups (which can be the same or different), M is a metal atom, and the asterisk “*” indicates species at the surface interface.

One representative implementation of this reaction scheme is depicted by FIGS. 2A through 2D, which show the formation of a poly(aluminum ethylene glycol) polymer (an “alucone”) by sequentially exposing a substrate to trimethylaluminum (TMA) (a multifunctional inorganic monomer) and ethylene glycol (EG) (a homo-bifunctional organic monomer). As in the ALD process described above, a TMA molecule first reacts with native surface hydroxyls (FIG. 2A) to form either one or two Al—O linkages. A free methane molecule is formed for each Al—O linkage produced (FIG. 2B). The next exposure to EG (FIG. 2C) displaces the methyl groups remaining from the TMA to form an aluminum-ethylene glycol unit. The reaction sequence then continues with another TMA exposure (FIG. 2D). Further continuation of the sequence results in an alucone polymeric film of arbitrary thickness.

Other representative metalcones that can be made using similar reaction pathways include, without limitation, those based on titanium (“titanicones”), zirconium (“zircones”), and zinc (“zincones”). Further examples of materials that can be deposited by MLD processes are known in the art, including ones disclosed in US Patent Publication No. US2008/102313 to Nilsen et al., which is incorporated herein in its entirety for all purposes by reference thereto.

### Deposition of ALD/MLD Alloys

It has further been discovered that a mixture of an inorganic oxide or nitride and a metalcone can be prepared by combining the ALD and MLD processes. By alternating ALD and MLD cycles, layers of both oxide/nitride and metalcone moieties are interspersed in the deposited material. Depending on the frequency of transition between ALD and MLD cycles, the resulting structure can be a homogeneous polymeric alloy or a structure that is partially or fully multilayered. By limiting the number of uninterrupted cycles of one type, the two moieties can be intimately mixed, and there is no discernible layering or other like microstructural features. Hence, a film produced in this manner may be termed an ALD/MLD alloy. The ALD/MLD alloy can be formed using a combination of any of the oxides or nitrides and any of the hybrid organic-inorganic, metal alkoxide polymers set forth above as the respective ALD and MLD components, although other combinations are also possible. The production of the alloy is generally simplified by using an oxide or nitride and an alkoxide of the same metal, but using ALD and MLD components based on different metals is also possible. Like the inorganic substances made by ALD, the hybrid polymer alloys of some embodiments produced by combined ALD/MLD processes are amorphous and exhibit a featureless microstructure. In an embodiment, the ALD/MLD alloy is optically transparent.

At the other extreme, material can be deposited with a large number of each cycle type between alternations, resulting in a microstructure having a discernible compositional modulation and possibly layers having distinct compositions, even though the film may remain amorphous. If even larger numbers of cycles of each type care carried out between alternations, the individual layers will have compositions that approach the respective ALD and MLD compositions. Such layering can be detected by various spectroscopic and imaging techniques, including direct electron microscopy, x-ray or neutron diffraction, and secondary ion mass spectroscopy (SIMS) or x-ray photoelectron spectroscopy (XPS) depth profiling, It is found that for deposition sequences that include no more than about 10 straight cycles, a structure that is alloyed and not discernibly layered is produced.

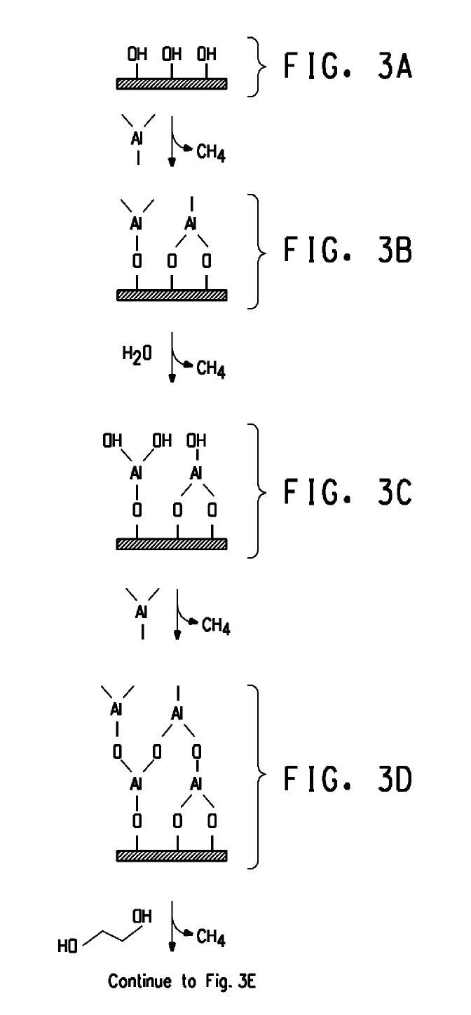

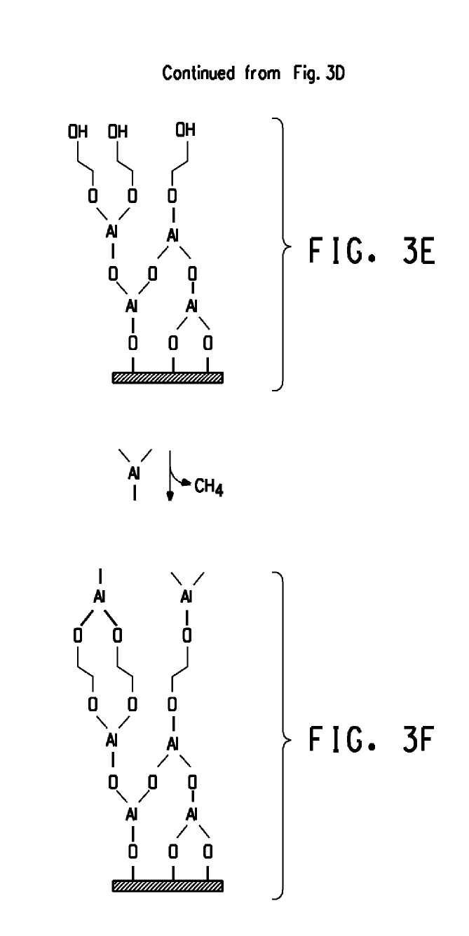

A representative implementation of a reaction scheme for depositing an ALD/MLD polymeric alloy is depicted schematically by FIGS. 3A through 3F. An initial substrate with pendant native surface hydroxyls (FIG. 3A) is first exposed to TMA vapor, which is adsorbed as a monolayer with formation of one or two Al—O linkages, respectively producing two or one free methane molecules (FIG. 3B). Next, the sample is exposed to water vapor or another oxidant, displacing methane molecules and again forming pendant hydroxyls (FIG. 3C), thus completing one ALD deposition cycle. Then, an MLD deposition cycle is carried out by exposing the substrate sequentially to TMA vapor (FIG. 3D) and EG (FIG. 3E). Thereafter, the alloy formation continues in like manner with another TMA exposure (FIG. 3F) and further alternating exposures to the reactants. It will be appreciated that the sequence depicted in FIGS. 3A through 3F, which represents strict alternation of single ALD and MLD deposition cycles, could be modified to provide alternating ALD and MLD deposition sequences, wherein each sequence could be composed of one or more of the deposition cycles shown, before switching to the opposite deposition type. By repeating the alternating ALD and MLD deposition sequences for a sufficient number of times, a film coating can be built to any desired, preselected thickness. Although the reaction sequence of FIG. 3 is shown as beginning with an ALD deposition sequence, a skilled person will recognize that the process could alternatively begin with an MLD deposition sequence. It will further be appreciated that processes like that of FIG. 3 represent a deposition producing an alloy that comprises inorganic and organic moieties that are intimately mixed and polymerically bonded. Because of the layer-by layer nature of the deposition, the alloy coating is highly conformal, like that of discrete ALD- or MLD-produced coatings.

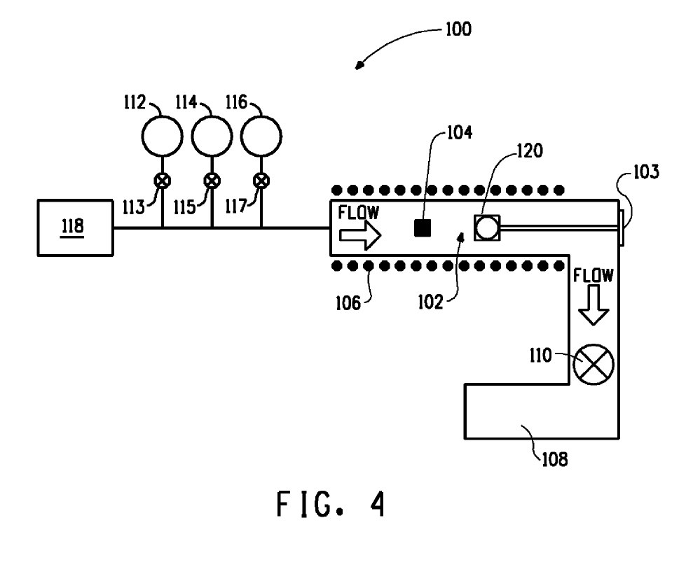

An aspect of the present disclosure provides a process and apparatus for depositing an ALD/MLD alloy on a polymeric substrate. In an embodiment, the process may be carried out in a reaction apparatus shown generally at 100 in FIG. 4. Ideally, the process might be implemented in a clean room or other comparable environment to minimize extraneous particulates that could give rise to defects. The alloy is deposited on a polymeric film substrate 104 that is situated in a reaction zone provided by reaction chamber 102 that can be evacuated (e.g., using a vacuum pump 108 controlled by valve 110). The chamber can be backfilled with a desired inert gas from a source 118. Alternatively, the chamber can be purged with flowing gas from source 118. For simplicity, only a single substrate sample 104 is shown, but it will be understood that chamber 102 may be designed to accommodate multiple samples. The substrate 104 is held at a temperature sufficiently high to drive the desired reactions, e.g., at 135-150° C. Heaters 106 may be used to supply heat to the chamber 102 and sample 104. Although a generally planar substrate 104 is depicted, the present alloy may also be deposited on any compatible substrate, including, without limitation, powders, generally two-dimensional sheet or film materials, or objects with more involved three-dimensional structure.

After substrate 104 is loaded through port 103 and chamber 102 is initially either evacuated or purged with inert gas, the substrate is subjected to ALD and MLD deposition sequences. Each ALD and MLD deposition sequence in turn comprises a preselected number of one or more ALD and MLD deposition cycles, respectively. ALD and MLD deposition sequences alternate until an alloy coating of the requisite thickness is formed on the substrate. The amount of material that has been accumulated is continuously monitored by any convenient means known in the art, e.g. using a quartz crystal microbalance 120.

In the implementation shown, the ALD process is carried out using TMA and H₂O, while the MLD process employs TMA and EG, using the respective pathways shown in reactions (1)-(4) delineated above. The TMA, EG, and H₂O are provided from respective sources 112, 114, and 116, which are associated with control valves 113, 115, and 117. Of course, this apparatus or modifications thereof may be used with other reactants to form other ALD/MLD alloys. The reactions may be carried out in a batch-type process in a chamber, as depicted in FIG. 4, or in a continuous process of suitable type.

Each ALD deposition cycle comprises: admitting an ALD precursor vapor to the chamber for a preselected period, purging the chamber with flowing inert gas, admitting a reactant vapor for a preselected period, and then purging the chamber again with flowing inert gas. The reaction is self-limiting, in that each cycle thus deposits approximately a monolayer of the desired substance, such as an oxide or nitride unit. In an embodiment appointed for depositing ALD alumina, the ALD precursor is trimethylaluminum from source 112, the reactant is an oxidant (e.g., water) from source 116, and the exposure time is about 2 seconds, with both gases introduced at a pressure of about 500 mT (67 Pa). Other ALD precursors and reactants may be used, and the exposure times and pressures for each may be the same or different.

Each MLD deposition cycle comprises: admitting an MLD precursor from source 112 to the chamber for a preselected period, purging the chamber with flowing inert gas, admitting a reactant from source 114, such as a homo- or hetero-multifunctional organic monomer, for a preselected period, and then purging the chamber again with flowing inert gas. In an embodiment appointed for depositing an alucone, the MLD precursor is trimethylaluminum, the reactant is ethylene glycol, and the exposure time is about 2 seconds, with both gases introduced at a pressure of about 500 mTorr (67 Pa). Other MLD precursors and reactants may be used, and the exposure times and pressures for each may be the same or different.

In an embodiment, both the ALD and MLD reactant vapors for each cycle may be supplied in an inert carrier gas. Inert gases useful either as carriers or for purging the chamber include, without limitation, He, Ar, and N₂. In both the ALD and MLD deposition cycles, the chamber alternatively may be evacuated after each exposure instead of purging with inert gas.

In an embodiment, the present alloy may have a composition wherein the molar fraction of the inorganic substance ranges from 0.1 to 0.9, the balance being metalcone and incidental impurities. In other embodiments, the molar fraction of the inorganic substance may range from 0.3 to 0.9, or 0.5 to 0.9, or 0.5 to 0.85.

The number of ALD and MLD deposition cycles in each pair of ALD and MLD deposition sequences need not be equal, permitting the effective local composition in the deposited alloy to be varied somewhat. Typically, the molar ratio of metalcone and inorganic substance is varied by changing the relative numbers of ALD and MLD deposition cycles in the respective ALD and MLD deposition sequences.

In an embodiment, each ALD deposition sequence comprises a preselected first number n₁ of ALD deposition cycles and MLD deposition sequence comprises a preselected second number n₂ of MLD deposition cycles, n₁ is 1 or more, n₂ is 1 or more, and a ratio n₁/(n₁+n₂) ranges from 0.1 to 0.9. By restricting the number of cycles in each deposition sequence, a well-mixed alloy may be prepared. For example, each of n₁ and n₂ may be at most 10 or at most 5.

In some embodiments, the relative number of ALD and MLD deposition cycles in successive deposition sequences may vary as the overall film is built up, allowing the production of a film with graded alloy composition and local properties.

A thickness range that is suitable for the present ALD/MLD alloy barrier coating to provide good gas permeation resistance is 5 nm to 100 nm, or 5 nm to 50 nm. Thinner layers ordinarily are more tolerant to flexing without causing the film to crack, which would potentially compromise barrier properties. This is especially beneficial for polymer substrates used for constructing certain devices, for which flexibility of the finished device is a desired property. Thin barrier films also increase transparency, which is beneficial for embodiments wherein protection is sought for optoelectronic devices which emanate or receive light. For a given process and alloy composition, a minimum thickness may be needed so that substantially all of the imperfections of the substrate are covered by the barrier coating. For a nearly defect-free substrate, the threshold thickness for acceptable barrier properties is estimated to be at least 2 nm, but may be as thick as 10 nm. ALD/MLD alloy barrier coatings as thin as 25 nm or 15 nm are often sufficient to reduce oxygen transport through a polymer film to a level below a measurement sensitivity of 0.0005 g-H₂O/m²/day.

In some instances, the surface to be coated with the present barrier material benefits from a treatment that promotes uniform and tenacious deposition. Suitable surface treatments may promote nucleation of the initial barrier layers and reduce the threshold thickness needed for good barrier properties. Without limitation, such treatment is found helpful with certain plastic or polymer substrate materials. Useful forms of treatment may be accomplished with chemical, physical, or plasma methods.

One such form comprises provision of a “starting” or “adhesion” layer is interposed between the substrate or article and the ALD/MLD alloy coating applied thereon. In various embodiments, the present barrier coating comprises an adhesion layer that promotes uniform deposition and tenacity of the present material over substantially the entire area being coated. Materials useful for the adhesion layer include ones conventionally deposited using ALD, such as aluminum oxide and silicon oxide, but other suitable materials may also be used. The adhesion layer material may be deposited by any suitable method, including ALD or by CVD, PVD, or another suitable deposition method known in the art. The adhesion layer may have a thickness of 1-100 nm, 1-50 nm, or 1-20 nm.

The synthesis of the present ALD/MLD combination barrier coatings may be carried out at a temperature such that the ALD and MLD reactions can proceed at an acceptably rapid rate and the coating quality is sufficiently good. The temperature may be selected to avoid any degradation of the substrate or other associated materials and to minimize adverse effects arising from any thermal mismatch between the substrate and the coating. A higher temperature also tends to accelerate the kinetics of the deposition reactions, which may beneficially improve overall cycle time. In different embodiments, and depending on the alloy composition, the deposition may be accomplished at a temperature of 50° C. to 500° C., 75° C. to 300° C., 100° C. to 200° C., or 125° C. to 175° C.

The combination of ALD alumina and MLD alucone beneficially provides acceptable deposition rates and alloy film quality, even at relatively low deposition temperatures, such as about 175° C. or below. Films made with this composition at 175° C. typically have an amorphous and featureless microstructure, which tends to result in good permeation barrier properties. Temperatures of 125° C. to 175° C. permit the deposition to be carried out on many common polymeric substrates, such as PET and PEN, as well as directly on many electronic devices and circuit elements. On the other hand, ALD/MLD alloy materials that may benefit from higher deposition temperatures can still be deposited on other materials (e.g., polyimides) and on devices that can tolerate a higher temperature exposure. Minimizing the deposition temperature beneficially reduces the propensity for cracking from thermal mismatch during cooldown.

In another aspect of the present disclosure, ALD/MLD alloy is useful in the construction of a variety of articles, including electronic devices. In various embodiments, the alloy may be disposed either directly on some or all of a device or on a carrier substrate that is subsequently incorporated in a finished device. For example, the alloy may be deposited as a barrier coating (optionally with a starting adhesion layer) directly on a circuit element of an electronic device. Optionally, the barrier coating in such embodiments includes an initial adhesion layer. Alternatively, the present barrier structure, incorporating a barrier coating on one or both of its major surfaces, can be used to construct devices, e.g. by affixing a barrier structure to one or both sides of an element sensitive to atmospheric gases or by encapsulating such devices. The barrier structure may be affixed to the device by any suitable method, including use of adhesive agents. Alternatively, the device may be affixed, e.g. to a circuit element, by directly forming the element on the barrier structure using methods known in the art of semiconductor fabrication.

Exemplary devices that may be constructed using the present alloy or barrier structure include, without limitation, ones that include a circuit element such as a semiconductor element, photovoltaic cell, OLED, or other optoelectronic device. Protection may be afforded by using the barrier structure on one or both sides of the circuit element. Optionally, the protection can be enhanced even further by layering more than one of the barrier structures.

For example, the present barrier structure can be used with thin-film PV cells fabricated as a roll product on metal foil or flexible substrates, with the barrier structure being included in the top or front sheet through which cells collect solar radiation, wherein the transparency and low permeability for moisture and other atmospheric gases are beneficial. Such thin-film PV devices include those based on film technologies such as amorphous silicon (a-Si), cadmium telluride (CdTe), copper indium (gallium) di-selenide/sulfide (CIS/CIGS), and dye-sensitized, organic and nano-materials.

### EXAMPLES

The operation and effects of certain embodiments of the present invention may be more fully appreciated from a series of examples (Examples 1-7), as described below. The embodiments on which these examples are based are representative only, and the selection of those embodiments to illustrate aspects of the invention does not indicate that materials, components, reactants, conditions, techniques and/or configurations not described in the examples are not suitable for use herein, or that subject matter not described in the examples is excluded from the scope of the appended claims and equivalents thereof.

### Example 1

### Alloy Fabrication and Water Vapor Transmission Measurements

In accordance with the present disclosure, alumina/alucone alloy films were grown on 100 mm diameter disks of 50-μm thick, flexible Kapton® EZ polyimide (available from DuPont, Wilmington, Del.) as a substrate.

The polyimide disks were affixed to conventional 4-inch diameter Si wafers and located in a hot-wall, viscous flow reactor. TMA (97%, Sigma Aldrich), EG (Reagent Plus >99%, Sigma Aldrich), and water (HPLC grade, Fisher Scientific) were used. Ultrahigh purity N₂ (Airgas) was used as the carrier gas and the purge between reactant exposures. The baseline reactor pressure was 600 mTorr (80 Pa) with N₂ flowing through the reactor. The substrate maintained at 135° C.

The film was formed by alternating deposition sequences of TMA/H₂O for ALD deposition of alumina and TMA/EG for MLD deposition of alucone. Different alloy compositions were obtained by varying the number of ALD deposition cycles in each ALD deposition sequence from 1 to 6, while each MLD deposition sequence comprised a single MLD cycle. The resulting films were denoted by the ratio of ALD to MLD cycles, wherein “n:m” represents a process in which the ALD and MLD deposition sequence respectively included “n” ALD cycles (n=1 to 6) and “m” MLD cycles (m=1). The resulting films were denoted by the ratio of ALD to MLD cycles as 1:1 through 6:1. The timing sequence for each cycle is defined by (t₁, t₂, t₃, t₄), wherein t₁ is the TMA exposure time, t₂ is the first N₂ purging time, t₃ is the water vapor or EG exposure time and t₄ is the second N₂ purging time. The timing sequences used are (0.8, 75, 0.2, 75) for the ALD of alumina and (0.6, 75, 0.9, 120) for MLD of alucone, all times measured in seconds. The reactant pressures were ˜250 mTorr (˜33 Pa). The ALD and MLD deposition sequences were repeated until a film thickness of about 25 nm was obtained, as indicated by a quartz crystal microbalance monitor located in the chamber.

For comparison, pure alumina and alucone films are grown to the same thickness using the same process conditions, but without any alternation between the respective deposition processes.

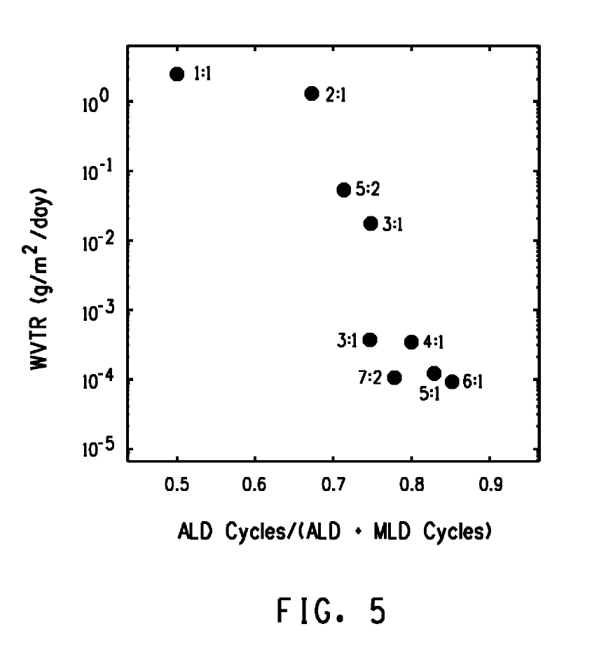

Water vapor transmission rates (WVTR) are measured for the alloy films using an Aquatran™ 1 system (available from MOCON®, Minneapolis, Minn.) that employs a coulometric sensor and NIST traceable calibration standards. This instrument has a WVTR sensitivity of <5×10⁻⁴ g/m²/day at 38° C./85% relative humidity (RH). The data obtained at 38° C. and 85% relative humidity are depicted in FIG. 5.

It is particularly surprising and unexpected that the WVTR of a 25 nm alumina/alucone alloy film drops very substantially as the ratio of ALD cycles to total ALD+MLD cycles exceeds about 0.7. Above about a 0.75 ratio, the WVTR of the alloy films falls below the effective detection limit of the MOCON® system, equaling what is seen for a pure ALD alumina film of the same total thickness similarly fabricated. A low WVTR is seen in the alloys, despite the dilution of the alumina moiety with alucone, which, by itself, has far higher gas vapor permeance, so that the behavior shown in FIG. 5 is not what would have been predicted by a simple rule of mixtures.

The substrate with the alumina/alucone barrier coating thereon is thus useful as a barrier structure.

### Example 2

### Alloy Fabrication and Water Vapor Transmission Measurements

In accordance with the present disclosure, alumina/zircone alloy films are grown on 100 mm diameter disks of 50-μm thick, flexible Kapton® EZ polyimide (available from DuPont, Wilmington, Del.) as a substrate. Except as noted, the depositions are carried out using the same techniques employed for the samples of Example 1 above.

The MLD deposition of zircone is carried out using zirconium(IV) tert-butoxide having the chemical formula Zr[OC(CH₃)₃]₄ and EG as the reactants. Different alloy compositions are obtained by varying the number of ALD deposition cycles in each ALD deposition sequence from 2 to 7, while each MLD deposition sequence comprised either one or two MLD cycles. The resulting films are denoted by the ratio of ALD to MLD cycles, wherein “n:m” represents a process in which each ALD deposition sequence includes “n” ALD cycles (n=2 to 7) and “m” MLD cycles (m=1 or 2). The ALD and MLD deposition sequences are repeated as in Example 1 until a film thickness of about 25 nm is obtained, as indicated by a quartz crystal microbalance monitor located in the chamber.

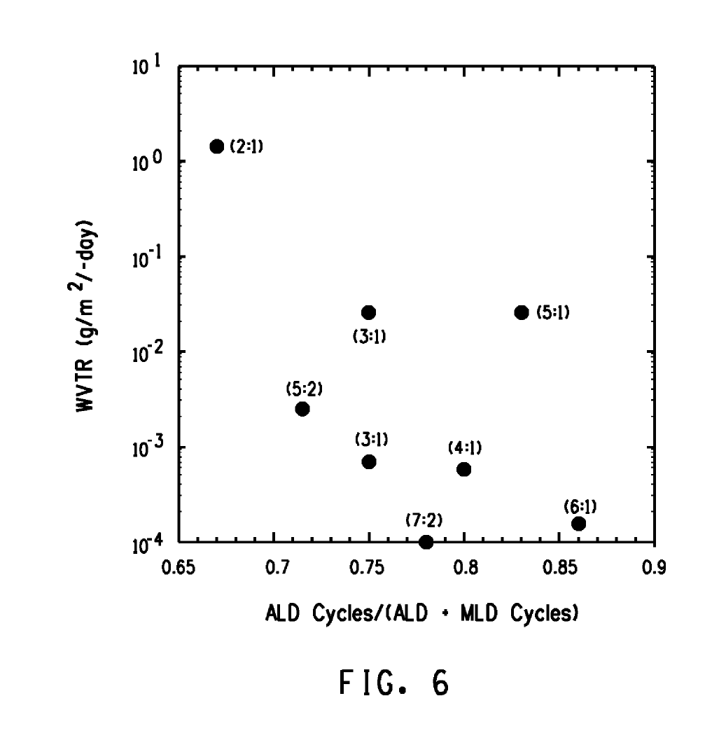

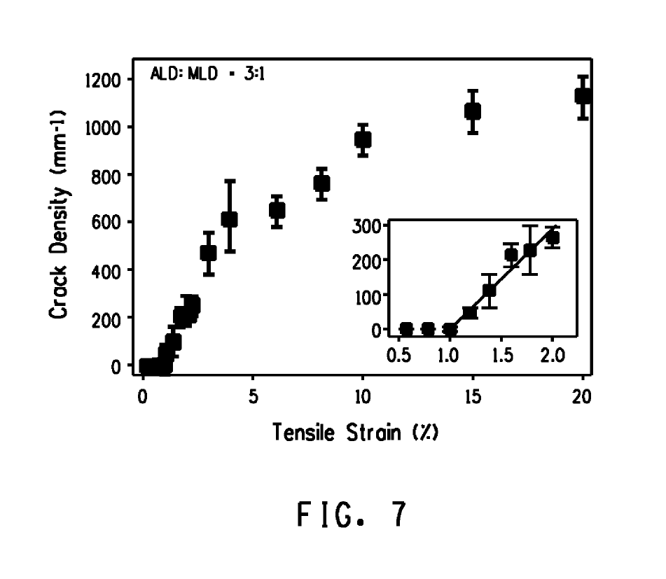

Water vapor transmission rates (WVTR) are again measured using a MOCON® Aquatran™ 1 system. The data obtained at 38° C. and 85% relative humidity for various alumina/zircone alloy films are depicted in FIG. 6. The compositional dependence of WVTR for 25 nm thick alumina/zircone alloy films is similar to that of the alumina/alucone films shown in FIG. 5, with WVTR again dropping sharply as the ratio of ALD cycles to total ALD+MLD cycles exceeds about 0.7.

The substrate with the alumina/zircone barrier coating thereon is thus useful as a barrier structure.

### Example 3

### Alloy Fabrication and Critical Tensile Strain Measurements

Films for tensile testing are deposited on 75-μm thick polyimide substrates obtained from CS Hyde Company, Inc., Lake Villa, Ill. Samples are cut into rectangles of 100 mm×10 mm and then placed in the same hot-wall, viscous flow reactor used for the experiments of Example 1. The same deposition protocol is used to prepare 100 nm thick films having 1:1, 3:1 and 6:1 alumina/alucone alloy compositions. Pure alumina and alucone films are also made using the same process, but without alternating ALD and MLD deposition sequences.

Tensile testing is carried out using an Insight 2 mechanical load-frame (MTS Systems Corp., Eden Prairie, Minn.). The coated samples are tensioned at room temperature (25° C.) to a prescribed strain, which is measured using a model LE-05 laser extensometer (Electronic Instrument Research Corp., Irwin, Pa.).

After the tensioning, the samples are then inspected for the presence of cracks using a Malachite Green (MG) dye tagging fluorescence technique. Malachite Green is a cationic, water-soluble, triphenylmenthane dye that has a strong binding energy with aromatic functional groups of the polyimide substrate. The MG molecules also contain an entity with a primary fluorescence emission peak centered on 670 nm when excited at shorter wavelengths.

To allow the MG dye to enter easily into cracks in the films, the 1:1, 3:1, and 6:1 alucone alloys are etched in 0.01 N, 0.1 N, and 1.0 N HCl solutions, respectively, for 10-30 min before tagging using 1.0 mM MG. Subsequently, the residue MG molecules are washed away distilled and deionized water. The samples are then dried using ultra high purity N₂ gas. The samples are then imaged using a confocal microscope (LSM 510, Carl Zeiss, Inc., Thornwood, N.Y.) equipped with an He—Ne laser with a wavelength of λ=633 nm. Any cracks present give rise to readily-detectable fluorescent emission.

The average film cracking density is determined from the number of observable cracks along the direction of the tensile strain over a length of 90 μm. The reported values of the crack density are obtained by averaging the density values taken with five different images.

The technique used to calculate critical tensile strain (CTS) is illustrated in FIG. 7, which plots average film cracking density versus tensile strain for the 3:1 ALD:MLD sample. The data show an onset of cracking, followed by a rapid increase in crack density, as the tensile strain increases. Each data point represents the average of data obtained at several different physical locations (typically 6 to 8) on the same sample. The error bar associated with each point represents ±1 standard deviation. The stress at the onset of cracking was determined as the intercept of a linear fit of the first few points, as shown in the inset in the FIG. 7 graph. For these data, the onset strain was determined as 0.98%, which is taken as the CTS for this film.

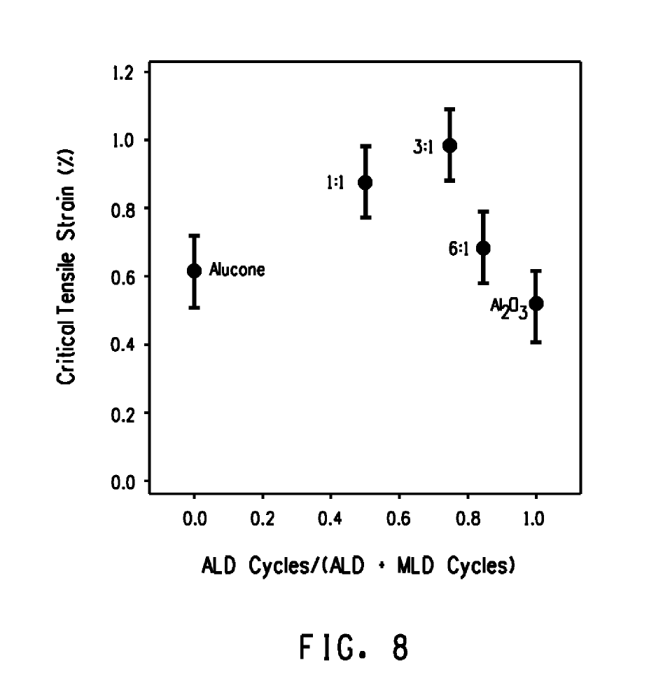

Similar analyses are applied to determine CTS values for the other samples. The measured CTS values are plotted versus composition in FIG. 8. It may be seen that alloy films of intermediate composition show a desirable increase in CTS over that of either a pure alumina or a pure alucone film, with the 1:1 and 3:1 alloys having nearly double the CTS of either pure film.

Taking together the data of FIGS. 5 and 8, it may be seen that alloy films of suitable composition can exhibit a combination of a low WVTR and a high CTS. In particular, certain alloy films exhibit WVTR rates as low as that of a pure alumina ALD film, while also having far higher CTS values than either pure alumina or pure alucone films. Coatings having such a combination are especially valuable in the production of electronic devices on made on flexible substrates but capable of maintaining their performance during and after flexure.

### Example 4

### Construction of a Light-Emitting Polymer Electronic Device

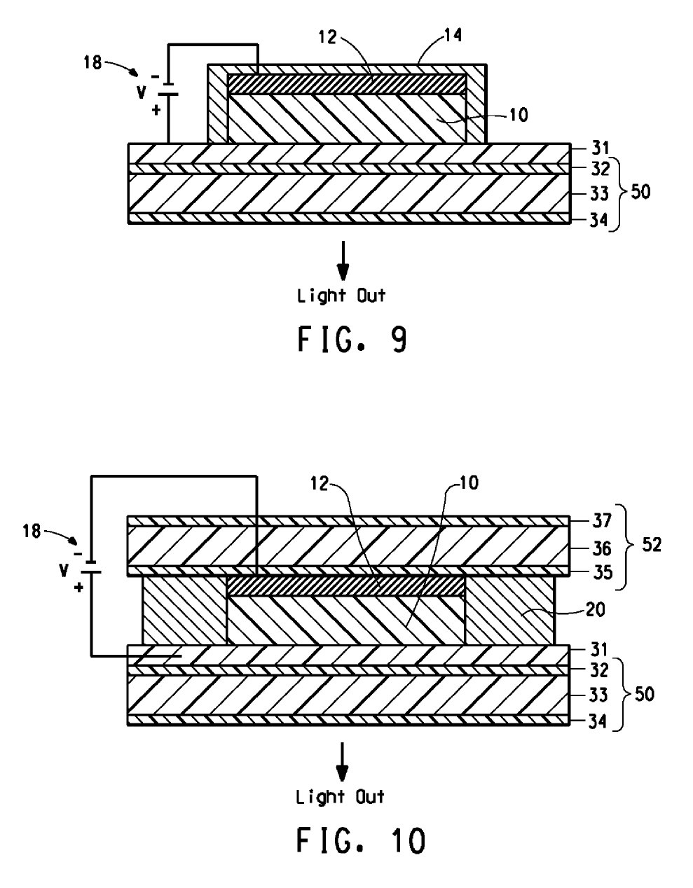

FIG. 9 shows a schematic representation of a light-emitting polymer electronic device that employs an alumina/alucone alloy of the present disclosure as a gas permeation barrier coating. For simplicity of illustration, the active circuit element of the light emitting polymer device is shown as a light-emitting polymer (LEP) 10 sandwiched between two electrodes. In practice, a hole-conducting and/or electron-conducting layer can be inserted between the appropriate electrode and the LEP layer to increase device efficiency. The anode 31 is a layer of indium-tin oxide and the cathode 12 is a Ca/Al layer composite. With a voltage 18 applied between the electrodes, holes injected at the anode and electrons injected at the cathode combine to form excitons which decay radiatively, emitting light from the LEP 10. The LEP is typically a photosensitive polymer such as poly-phenylene vinylene (PPV) or a derivative thereof. The cathode is frequently Ba or Ca and is extremely reactive with atmospheric gases, especially water vapor. Because of the use of these sensitive materials, the device packaging needs to exclude atmospheric gases in order to achieve reasonable device lifetimes.

In FIG. 9, the package comprises a barrier structure 50, which in turn comprises a carrier substrate 33 coated on each of its major surfaces with a 32.5 nm thick film of an alumina/alucone alloy 32, 34. The alloy layers are deposited by a combination ALD/MLD process as described herein. Substrate 33 can be plastic or glass. Optionally, the material of substrate 33 is flexible, meaning that it can be bent to a round radius of less than 3 mm. As shown, substrate 33 is comprised of a 0.004 inch (100 μm) thick polyethylene naphthalate (PEN) polyester film.

Barrier structure 50 is prepared using the deposition process described in Example 1 above, with each ALD deposition sequence comprising 4 ALD deposition cycles done with TMA and water vapor and each MLD deposition sequence comprising a single MLD deposition cycle using TMA and EG. The ALD and MLD deposition sequences are carried out in alternation approximately 50 times to obtain a coating about 32.5 nm thick on each side of the PEN carrier substrate.

Barrier structure 50 is then coated with indium-tin oxide 31 transparent conductor by RF magnetron sputtering from a 10% (by weight) Sn-doped indium oxide target. The ITO film thickness is 150 nm. The LEP is spin coated on the ITO electrode, after which a cathode 12 of 5 nm Ca with about 1 μm of Al are thermally evaporated from Ca and Al metal sources, respectively.

The LEP device is then coated with a 32.5 nm-thick, top barrier coating 14 of an alumina-alucone alloy, applied using the same process employed to form the coatings of barrier structure 50. A 4:1 alloy is again employed.

The resulting structure is now impervious to atmospheric gases.

### Example 5

### Construction of a Light-Emitting Polymer Electronic Device

A light-emitting polymer electronic device similar to that of Example 3, but employing another variation of the packaging, is shown in FIG. 10. The device is prepared using the same processes used to prepare the device of Example 3, but with the top barrier coating 14 being replaced by a second barrier structure 52 similar to barrier structure 50. This capping barrier structure 52 is sealed to the substrate barrier using a layer 20 of epoxy.

### Example 6

### Construction of an Organic Transistor Device

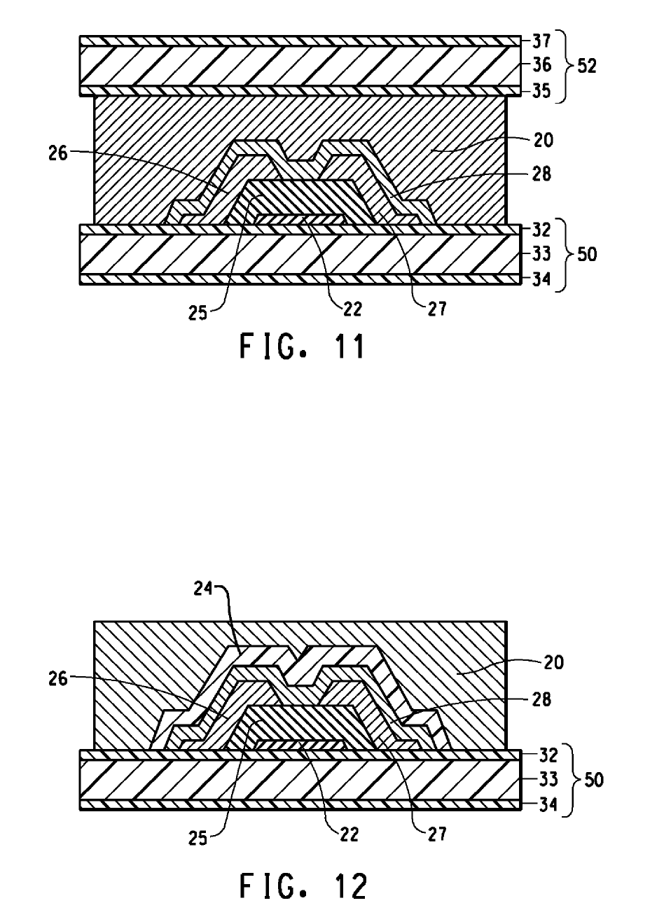

FIG. 11 illustrates a protection strategy for an electronic device comprising an organic transistor circuit element. The device incorporates barrier coatings produced using the present combination ALD/MLD process. The transistor shown is a bottom gate structure with the organic semiconductor 28 as the final or top layer. Because most organic semiconductors are air sensitive and prolonged exposure degrades their properties, protection strategies are necessary.

In FIG. 11 the package employs barrier structure 50 similar to that discussed in Examples 3 and 4 above. Structure 50 thus comprises a substrate 33 coated on each of its major surfaces with a 32.5 nm thick film of a 4:1 alumina/alucone alloy 32, 34, which may be deposited by a combination ALD/MLD process as described herein. The transistor is deposited on barrier structure 50 and then sealed to a second barrier structure 52 similar to that shown in FIG. 10. The substrate 36 is comprised of a polyester film, polyethylene naphthalate (PEN), 0.004 inch (100 μm) thick. Each major surface of the PEN film is coated with a 32.5 nm thick film of an alumina/alucone alloy 35, 37, which is deposited by a combination ALD/MLD process. A gate electrode 22 of 100 nm thick Pd metal is ion-beam sputtered through a shadow mask onto the barrier layer 32. A gate dielectric 25 of 250 nm Si₃N₄ is then deposited by plasma-enhanced chemical vapor deposition, also through a mask to allow contact to the metal gate. This is followed by patterning of 100 nm-thick Pd source 26 and drain 27 electrodes, ion beam sputtered on the gate dielectric 25. Finally the top organic semiconductor 28, e.g., pentacene, is thermally evaporated through a shadow mask that allows contact to source-drain electrodes. The entire transistor is capped with a second barrier structure 52 (similar to that depicted in FIG. 10) which is sealed with an epoxy sealant 20 to barrier structure 50, thereby encapsulating and protecting the transistor.

### Example 7

### Construction of an Organic Transistor Device

FIG. 12 depicts another configuration of an electronic device comprising an organic transistor circuit element, wherein the second barrier structure of Example 5 is replaced by a single conformal, 32.5 nm-thick layer 24 of a 4:1 alumina/alucone alloy, which may be deposited by a combination ALD/MLD process as described herein. Both packaging structures for the organic transistor are impervious to atmospheric gases. Alternatively, barrier structure 50 can be replaced by an impermeable glass substrate. Optionally, an initial 4 nm thick adhesion layer of silicon nitride (not shown) is deposited by plasma-enhanced chemical vapor deposition at room temperature before layer 24 is applied.

Having thus described the invention in rather full detail, it will be understood that such detail need not be strictly adhered to, but that additional changes and modifications may suggest themselves to one skilled in the art. It is to be understood that the present PV cell and its manufacture may be implemented in various ways, using different equipment and carrying out the steps described herein in different orders. All of these changes and modifications are to be understood as falling within the scope of the invention as defined by the subjoined claims.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range

In this specification, unless explicitly stated otherwise or indicated to the contrary by the context of usage,

(a) amounts, sizes, ranges, formulations, parameters, and other quantities and characteristics recited herein, particularly when modified by the term “about”, may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value; and

(b) all numerical quantities of parts, percentage, or ratio are given as parts, percentage, or ratio by weight; the stated parts, percentage, or ratio by weight may or may not add up to 100.

1. A process for manufacturing an alloy comprising the steps of:
(a) providing a substrate in a reaction zone;
(b) carrying out a first deposition sequence comprising at least one first deposition cycle comprising in sequence the steps of:
(b1) admitting into the reaction zone a first reactant precursor vapor capable of forming an adsorbed layer on the substrate,
(b2) purging the reaction zone to remove unadsorbed first reactant precursor vapor,
(b3) admitting into the reaction zone a second reactant precursor vapor under thermal conditions that promote a reaction of the second reactant precursor vapor and adsorbed first reactant precursor vapor, and
(b4) purging the reaction zone of volatile reactants and reaction products produced in step (b3);
(c) thereafter carrying out a second deposition sequence comprising at least one second deposition cycle comprising in sequence the steps of:
(c1) admitting into the reaction zone a third reactant precursor vapor capable of forming an adsorbed layer on the substrate,
(c2) purging the reaction zone to remove unadsorbed third reactant precursor vapor,
(c3) admitting into the reaction zone a fourth reactant precursor vapor under thermal conditions that promote a reaction of the fourth reactant precursor vapor and adsorbed third reactant precursor vapor, and
(c4) purging the reaction zone of volatile reactants and reaction products produced in step (c3); and
(d) thereafter repeating in alternation the first and second deposition sequences for a number of times sufficient to form the alloy on the substrate in a preselected thickness.

2. The process of claim 1, wherein at least some of the purging steps are carried out by flowing an inert gas through the reaction zone.

3. The process of claim 1, wherein at least some of the purging steps are carried out by evacuating the reaction zone.

4. The process of claim 1, wherein the first and second deposition sequences are carried out at a temperature of 50 to 250° C.

5. The process of claim 1, wherein each first deposition sequence comprises a preselected first number n₁ of first deposition cycles and each second deposition sequence comprises a preselected second number n₂ of second deposition cycles, n₁ is 1 or more, n₂ is 1 or more, and a ratio n₁/(n₁+n₂) ranges from 0.1 to 0.9.

6. The process of claim 5, wherein each of n₁ and n₂ is at most 10.

7. The process of claim 1, wherein the first reactant precursor vapor and the second reactant precursor vapor react to form an inorganic substance.

8. The process of claim 1, wherein the inorganic substance is an oxide or nitride.

9. The process of claim 1, wherein the inorganic substance is an oxide or nitride of an element of Groups IVB, VB, VIB, IIIA, or IVA of the Periodic Table or a combination thereof.

10. The process of claim 1, wherein the inorganic substance is aluminum oxide, silicon dioxide, titanium dioxide, zirconium dioxide, or silicon nitride, or a combination thereof.

11. The process of claim 1, wherein the third reactant precursor vapor and the fourth reactant precursor vapor react to form a metalcone.

12. The process of claim 11, wherein the metalcone is an alucone, a zincone, a titanicone, or a zircone.

13. The process of claim 1, wherein the first reactant precursor vapor and the second reactant precursor vapor react to form alumina and the third reactant precursor vapor and the fourth reactant precursor vapor react to form an alucone.

14. The process of claim 1, wherein the substrate is glass or plastic.

15. The process of claim 1, wherein the substrate is a flexible polymer.

16. The process of claim 1, further comprising a surface treatment of the substrate prior to step (a).

17. A process for manufacturing a barrier structure comprising the steps of:
(a) providing a carrier substrate having opposing first and second major surfaces in a reaction zone; and
(b) carrying out a first deposition sequence comprising at least one first deposition cycle comprising in sequence the steps of:
(b1) admitting into the reaction zone a first reactant precursor vapor capable of forming an adsorbed layer on at least the first major surface of the carrier substrate,
(b2) purging the reaction zone to remove unadsorbed first reactant precursor vapor,
(b3) admitting into the reaction zone a second reactant precursor vapor under thermal conditions that promote a reaction of the second reactant precursor vapor and adsorbed first reactant precursor vapor, and
(b4) purging the reaction zone of volatile reactants and reaction products produced in step (b3);
(c) thereafter carrying out a second deposition sequence comprising at least one second deposition cycle comprising in sequence the steps of:
(c1) admitting into the reaction zone a third reactant precursor vapor capable of forming an adsorbed layer on at least the first major surface of the carrier substrate,
(c2) purging the reaction zone to remove unadsorbed third reactant precursor vapor,
(c3) admitting into the reaction zone a fourth reactant precursor vapor under thermal conditions that promote a reaction of the fourth reactant precursor vapor and adsorbed third reactant precursor vapor, and,
(c4) purging the reaction zone of volatile reactants and reaction products produced in step (c3); and
(d) thereafter repeating in alternation the first and second deposition sequences for a number of times sufficient to form the alloy on at least the first major surface of the carrier substrate in a preselected thickness.

18. The process of claim 17, wherein the alloy is formed on both the major surfaces of the carrier substrate.

19. The process of claim 17, wherein the substrate is a flexible polymer.

20. A process for constructing an electronic device comprising:
(a) providing a circuit element having opposing first and second sides; and
(b) affixing onto the first side of the circuit element a first barrier structure manufactured using the process of claim 17.

21. The process of claim 20, wherein the carrier substrate of the first barrier structure is a flexible polymer.

22. The process of claim 20, further comprising:
(c) affixing onto the second side of the circuit element a second barrier structure manufactured using the process of claim 17.

23. The process of claim 22, wherein the carrier substrates of the first and second barrier structures are flexible polymers.

24. The process of claim 20, further comprising:
(c) applying onto the second side of the circuit element a barrier coating comprising an alloy comprising an inorganic substance and a metalcone that are polymerically linked.

25. A process for constructing an electronic device comprising:
(a) providing a circuit element having opposing first and second sides; and
(b) applying onto the first side of the circuit element a barrier coating comprising an alloy comprising an inorganic substance and a metalcone that are polymerically linked.

26. The process of claim 25, wherein the barrier coating comprises an adhesion layer interposed between the circuit element and the alloy.

27. An electronic device comprising:
(a) a circuit element;
(b) a barrier coating disposed on the circuit element and comprising an alloy comprising an inorganic substance and a metalcone that are polymerically linked.

28. The electronic device of claim 27, wherein the barrier coating further comprises an adhesion layer to which the alloy is adhered.

29. The electronic device of claim 27, wherein the alloy consists essentially of a molar fraction ranging from 0.1 to 0.9 of the inorganic substance, the balance being the metalcone and incidental impurities.

30. The electronic device of claim 27, wherein the barrier coating has a total thickness of at most 25 nm and a water vapor transmission rate of less than 0.0005 g-H₂O/m²-day, when measured at 38° C. and 85% relative humidity.

31. The electronic device of claim 27, wherein the barrier coating is disposed directly on the circuit element.

32. The electronic device of claim 30, wherein the barrier coating has a thickness ranging from 2 nm to 100 nm.

33. The electronic device of claim 27, further comprising a first carrier substrate having opposing first and second major surfaces and wherein the barrier coating is disposed on at least the first major surface of the first carrier substrate and the carrier substrate is affixed to the circuit element.

34. The electronic device of claim 33, wherein the barrier coating further comprises an adhesion layer interposed between the first major surface of the carrier substrate and the alloy.

35. The electronic device of claim 33, wherein a portion of the barrier coating is disposed on each of the major surfaces of the first carrier substrate.

36. The electronic device of claim 33, wherein the first carrier substrate is glass.

37. The electronic device of claim 33, wherein the first carrier substrate is a polymer.

38. The electronic device of claim 33, wherein the first carrier substrate is a flexible polymer.

39. The electronic device of claim 33, wherein the barrier coating has a thickness ranging from 2 nm to 100 nm.

40. The electronic device of claim 33, wherein the alloy consists essentially of a molar fraction ranging from 0.1 to 0.9 of the inorganic substance, the balance being the metalcone and incidental impurities.

41. The electronic device of claim 33, wherein the barrier coating has a total thickness of at most 25 nm and a water vapor transmission rate of less than 0.0005 g-H₂O/m²-day through a thickness of 15 nm, when measured at 38° C. and 85% relative humidity.

42. The electronic device of claim 33, further comprising a second carrier substrate having opposing first and second major surfaces and wherein a portion of the barrier coating is further disposed on at least the first major surface of the second carrier substrate and the second carrier substrate is affixed to the circuit element.

43. The electronic device of claim 27, wherein the circuit element is a semiconductor element.

44. A photovoltaic cell device comprising the electronic device of claim 43.

45. An OLED display comprising the electronic device of claim 43.
